(19) United States
(12) Patent Application Publication
(10) Pub. No.: US 2007/0158817 A1
(43) Pub. Date: Jul. 12, 2007

(54) Semiconductor device

(75) Inventors: Takumi Katoh, Kyoto (JP); Hideo Hara, Kyoto (JP)

Correspondence Address: ROHM CO., LTD.;C/O KEATING & BENNETT, LLP, 8180 GREENSBORO DRIVE, SUITE 850, MCLEAN, VA, 22102, US

(73) Assignee: ROHM CO., LTD., Ukyo-ku, Kyoto (JP)

(21) Appl. No.: 10/598,804

(22) PCT Filed: Mar. 11, 2005
(86) PCT No.: PCT/JP05/04337

§ 371 Date: Sep. 12, 2006

(30) Foreign Application Priority Data
Mar. 12, 2004 (JP) 2004-070380

(51) Int. Cl. H01L 23/52

(52) U.S. Cl. 257/691; 257/E23.079

(57) ABSTRACT

A semiconductor device includes, in first and second power source systems, electrostatic discharge (ESD) protective bonding pads connected by bonding wires to first and second power supply terminals and first and second ground terminals, first and second signal ESD protective element sections that are each connected to first and second signal bonding pads and the ESD protective bonding pads and protect first and second I/O circuits, respectively, and a power source ESD protective element section connected to first and second ESD protective bonding pads. The semiconductor device is capable of minimizing an increase in the chip size while implementing ESD damage countermeasures in which the power supply (or ground) terminal of one power source system serves as the reference potential terminal for the signal terminal of the other power source system.

### BACKGROUND OF THE INVENTION

1. Field of the Invention

The present invention relates to a semiconductor device having a plurality of power source systems.

2. Description of the Related Art

Conventionally, a semiconductor device having a plurality of power source systems, that is, a semiconductor device including a plurality of pairs of power supply terminals and ground terminals in which semiconductor elements are provided between the respective power supply terminal and ground terminal has utilized electrostatic discharge (ESD) countermeasures. The ESD countermeasures use all of the power supply terminals and ground terminals serving as the reference potential terminals so that there is no damage caused by ESD even when static electricity applied to a signal terminal is discharged via any of the power supply terminals and ground terminals (see, e.g., Japanese Patent Application Laid-open No. H8-148650).

FIG. 4 is a partial circuit diagram showing the connection state of the respective terminals of a conventional semiconductor device having two power source systems which are a digital power source system and an analog power source system. This semiconductor device 101 includes, for example, in a 5V digital power source system, a power supply (VCC1) terminal 110, a ground (GND1) terminal 112, and at least one signal (SIG1) terminal 111 that inputs or outputs a signal from or to the outside; and similarly, in a 5V analog power source system, a power supply (VCC2) terminal 113, a ground (GND2) terminal 115, and at least one signal (SIG2) terminal 114 that inputs or outputs a signal from or to the outside. The respective terminals are connected to a VCC1 bonding pad 130, a GND1 bonding pad 132, a SIG1 bonding pad 131, a VCC2 bonding pad 133, a GND2 bonding pad 135, and a SIG2 bonding pad 134 via bonding wires 120 to 125.

The VCC1 bonding pad 130 and GND1 bonding pad 132 are connected to VCC1 wiring 150 and GND1 wiring 152, respectively, that are provided on a semiconductor substrate. The VCC1 wiring 150 and GND1 wiring 152 are connected to the elements of at least one of an I/O circuit 143 and an internal circuit 145 of the digital power source system and to a signal ESD protective element section 141, which will be described subsequently. The I/O circuit 143 inputs or outputs a signal from or to the SIG1 bonding pad 131 and the internal circuit 145 performs signal processing in accordance with a signal inputted from the I/O circuit 143 or outputs a signal to the I/O circuit 143. Specific elements for inputting are not illustrated in the I/O circuit 143 in FIG. 4, or subsequently described I/O circuit 144.

The above described signal ESD protective element section 141 prevents damage to the I/O circuit 143 caused by ESD and is defined by a VCC1-side protective element for discharging static electricity which is applied to the SIG1 terminal 111 with VCC1 terminal 110 serving as the reference potential terminal, to VCC1 terminal 110, and a GND1-side protective element for discharging static electricity which is applied to the SIG1 terminal 111 with the GND1 terminal 112 serving as the reference potential terminal, to the GND1 terminal 112. These protective elements specifically use a diode shown in FIG. 4, a field transistor (MOS transistor with a high threshold value in which the gate is formed by metal wiring), or the like. Thus, ESD countermeasures in which the VCC1 terminal 110 and GND1 terminal 112 serve as the reference potential terminal for the SIG1 terminal 111 are used. ESD countermeasures in which a VCC2 terminal 113 and a GND2 terminal 115 of the other power source system serve as the reference potential terminal will be described below.

The VCC2 bonding pad 133 and GND2 bonding pad 135 are connected to VCC2 wiring 153 and GND2 wiring 155, respectively, that are provided on a semiconductor substrate. The VCC2 wiring 153 and GND2 wiring 155 are connected to the elements of at least one of an I/O circuit 144 and an internal circuit 146 of the analog power source system and to a signal ESD protective element section 142. The I/O circuit 144 inputs or outputs a signal from or to the SIG2 bonding pad 134 and the internal circuit 146 performs signal processing in accordance with a signal inputted from the I/O circuit 144 or outputs a signal to the I/O circuit 144. The signal ESD protective element section 142 also prevents damage to the I/O circuit 144 caused by ESD and the construction and functions of the signal ESD protective element section 142 are substantially the same as those of the signal ESD protective element section 141.

A power source ESD protective element section 140 prevents damage caused by ESD to the elements of the I/O circuits 143 and 144 or the internal circuits 145 and 146 even in cases where static electricity is applied between any of the power supply terminals or ground terminals and is defined by a protective element (one diode) between the VCC1 terminal 110 and GND1 terminal 112, a protective element (one diode) between the VCC2 terminal 113 and GND1 terminal 112, a protective element (one diode) between the VCC2 terminal 113 and GND2 terminal 115, a protective element (two diodes) between the GND2 terminal 115 and GND1 terminal 112, a protective element (two diodes) between the VCC1 terminal 110 and VCC2 terminal 113, and a protective element (one diode) between the VCC1 terminal 110 and GND2 terminal 115. The protective element between the GND2 terminal 115 and GND1 terminal 112 and the protective element between the VCC1 terminal 110 and VCC2 terminal 113 are defined by two mutually reversed diodes because of their high protection capacity with respect to ESD. This construction is possible because the cathode and anode of the diodes have the same potential. The protection capacity of the other protective elements (the protective element between the VCC1 terminal 110 and GND1 terminal 112 and so forth, for example) is increased by further increasing the surface area of the protective elements.

The operation of ESD damage prevention in which the VCC2 terminal 113 and GND2 terminal 115 of the other power source system serve as the reference potential terminal for the SIG1 terminal 111 will be described next. The static electricity applied to the SIG1 terminal 111 for which VCC2 terminal 113 serves as the reference potential terminal is discharged to the VCC2 terminal 113 via the VCC1-side protective element defining the signal ESD protective element section 141, the VCC1 wiring 150, the protective element between the VCC1 terminal 110 and VCC2 terminal 113 defining the power source ESD protective element section 140, and the VCC2 wiring 153. The static electricity applied to the SIG1 terminal 111 for which the GND2 terminal 115 serves as the reference potential terminal is also similarly discharged to the GND2 terminal 115 via the GND1-side protective element defining the signal ESD protective element section 141, the GND1 wiring 152, the protective element between the GND2 terminal 115 and GND1 terminal 112 defining the power source ESD protective element section 140, and the GND2 wiring 155. Similarly, damage prevention for ESD with the VCC1 terminal 110 and GND1 terminal 112 of the other power source system serving as the reference potential terminal for the SIG2 terminal 114 is implemented via the signal ESD protective element section 142 and the power source ESD protective element section 140.

Thus, in a semiconductor device having a plurality of power source systems, ESD countermeasures for a signal terminal of either power source system with a power supply terminal or a ground terminal of the other power source system serving as the reference potential terminal implement damage prevention via the signal ESD protective element section and the power source ESD protective element section. The semiconductor device 101 is a semiconductor device having two power source systems including a digital power source system and an analog power source system as the plurality of power source systems, but is not limited to such an arrangement. For example, ESD damage prevention with a power supply terminal or a ground terminal of the other power source system serving as the reference potential terminal can also be implemented by providing the power source ESD protective element section 140 in a semiconductor device having a plurality of power source systems of different power supply voltages such as a 5V power source system and a 3V power source system. However, assuming that the VCC1 terminal 110 is 5V and the VCC2 terminal 113 is 3V, the protective element between the VCC1 terminal 110 and VCC2 terminal 113 of the power source ESD protective element section 140 is defined by one diode (or field transistor or the like) that is reverse-biased in normal operation.

However, the power source ESD protective element section in the semiconductor device having a plurality of power source systems is defined by protective elements between a large number of power supply terminals and ground terminals as in the case of the power source ESD protective element section 140 of the semiconductor device 101, and each of the protective elements occupies a large surface area. Hence, in the semiconductor device, it is not sufficient merely to arrange the power source ESD protective element section in an empty space where the elements of the internal circuits and I/O circuits are not disposed. A space for the power source ESD protective element section must be provided in addition to the space of the internal circuits and I/O circuits, which therefore causes an increase in the chip size.

### SUMMARY OF THE INVENTION

In order to overcome the problems described above, preferred embodiments of the present invention provide, in a semiconductor device having a plurality of power source systems, a semiconductor device that is capable of minimizing an increase in the chip size while implementing ESD damage prevention for a signal terminal of either power source system with a power supply terminal or a ground terminal of the other power source system serving as the reference potential terminal.

The semiconductor device according to a preferred embodiment of the present invention is a semiconductor device having at least first and second power source systems as a plurality of power source systems, the first and second power source systems each including a power supply bonding pad, a ground bonding pad, and at least one signal bonding pad that are provided on a semiconductor substrate, respectively; and an I/O circuit that is connected to each of the bonding pads and which inputs or outputs a signal from or to the signal bonding pad; wherein each of the first and second power source systems includes, on the semiconductor substrate, a first ESD protective bonding pad and a signal ESD protective element section that is connected to the signal bonding pad and the first ESD protective bonding pad, and wherein the first ESD protective bonding pads of the first and second power source systems are connected to one another.

Preferably, each of the first and second power source systems of the semiconductor device, depending on the case, further includes, on the semiconductor substrate, a second ESD protective bonding pad that is connected to the signal ESD protective element section, wherein the second ESD protective bonding pads of the first and second power source systems are connected to one another.

The semiconductor device preferably further includes a power source ESD protective element section that is connected to either of the first ESD protective bonding pads (and, depending on the case, the second ESD protective bonding pads) of the first and second power source systems.

In the semiconductor device, each of the first and second power source systems preferably includes a power supply terminal that is connected to the power supply bonding pad; a ground terminal that is connected to the ground bonding pad; and a signal terminal that is connected to the signal bonding pad; wherein, in each of the first and second power source systems, the first ESD protective bonding pad is connected to one of the power supply terminal and the ground terminal (and, depending on the case, the second ESD protective bonding pad is connected to the other of the power supply terminal and the ground terminal).

Bonding wires are preferably used for the connections between the bonding pads and terminals.

The semiconductor device according to various preferred embodiments of the present invention is preferably provided with an ESD protective bonding pad in addition to a power supply bonding pad and ground bonding pad in the respective power source system of a semiconductor device having a plurality of power source systems, and discharges static electricity applied to a signal terminal via the ESD protective bonding pad. As a result, an increase in the chip size can be minimized and prevented, while implementing ESD damage countermeasures for a signal terminal of one power source system with a power supply terminal or a ground terminal of the other power source system serving as the reference potential terminal.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a partial circuit diagram of a semiconductor device of a first preferred embodiment of the present invention.

FIG. 2 shows the overall layout of the semiconductor device.

FIG. 3 is a partial circuit diagram of a semiconductor device of a second preferred embodiment of the present invention.

FIG. 4 is a partial circuit diagram of a conventional semiconductor device.

### DETAILED DESCRIPTION OF PREFERRED EMBODIMENTS

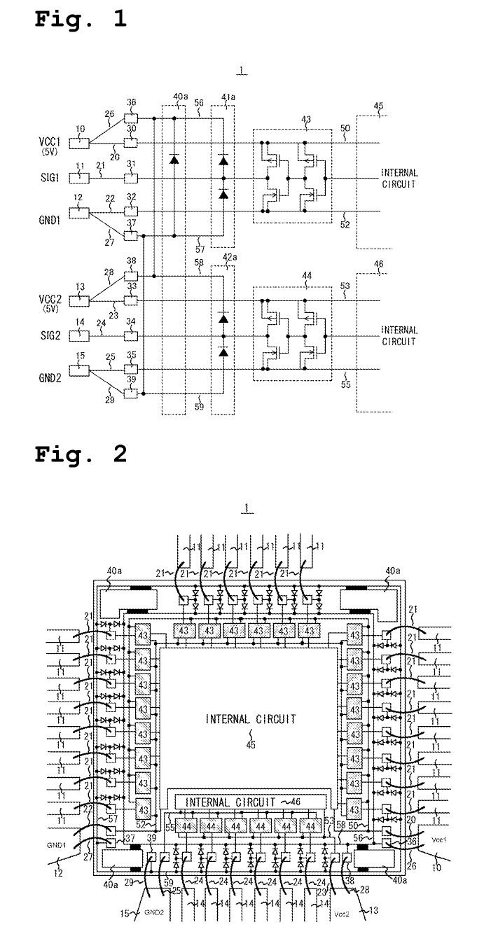

Preferred embodiments of the present invention will be described hereinbelow with reference to the drawings. FIG. 1 is a partial circuit diagram showing the connected state of each of the terminals in a semiconductor device of a first preferred embodiment of the present invention. The semiconductor device 1 has, as a plurality of power source systems, two power source systems which are a 5V digital power source system (first power source system) and a 5V analog power source system (second power source system).

The first power source system includes a power supply (VCC1) terminal 10, a ground (GND1) terminal 12, and at least one signal (SIG1) terminal 11 that inputs or outputs a signal from or to the outside of the semiconductor device 1. The second power source system includes a power supply (VCC2) terminal 13, a ground (GND2) terminal 15, and at least one signal (SIG2) terminal 14 that inputs or outputs a signal from or to the outside of the semiconductor device 1. The first power source system includes, on a semiconductor substrate, a power supply (VCC1) bonding pad 30, a ground (GND1) bonding pad 32, and at least one signal (SIG1) bonding pad 31. The second power source system includes, on the semiconductor substrate, a power supply (VCC2) bonding pad 33, a ground (GND2) bonding pad 35, and at least one signal (SIG2) bonding pad 34. The VCC1 terminal 10, SIG1 terminal 11, GND1 terminal 12, VCC2 terminal 13, SIG2 terminal 14, and GND2 terminal 15 are connected to the VCC1 bonding pad 30, SIG1 bonding pad 31, GND1 bonding pad 32, VCC2 bonding pad 33, SIG2 bonding pad 34, and GND2 bonding pad 35 via bonding wires 20 to 25, respectively.

In the first power source system, a VCC1 ESD protective bonding pad (second ESD protective bonding pad of the first power source system) 36 is provided in the vicinity of the VCC1 bonding pad 30 and a GND1 ESD protective bonding pad (first ESD protective bonding pad of the first power source system) 37 is provided in the vicinity of the GND1 bonding pad 32, on the semiconductor substrate. In the second power source system, a VCC2 ESD protective bonding pad (second ESD protective bonding pad of second power source system) 38 is provided in the vicinity of the VCC2 bonding pad 33 and a GND2 ESD protective bonding pad (first ESD protective bonding pad of the second power source system) 39 is provided in the vicinity of the GND2 bonding pad 35, on the semiconductor substrate. The ESD protective bonding pads 36, 37, 38, and 39 are connected to the VCC1 terminal 10, GND1 terminal 12, VCC2 terminal 13, and GND2 terminal 15 via bonding wires 26 to 29, respectively. The VCC1 ESD protective bonding pad 36 and VCC2 ESD protective bonding pad 38 are connected to one another and the GND1 ESD protective bonding pad 37 and GND2 ESD protective bonding pad 39 are connected to one another.

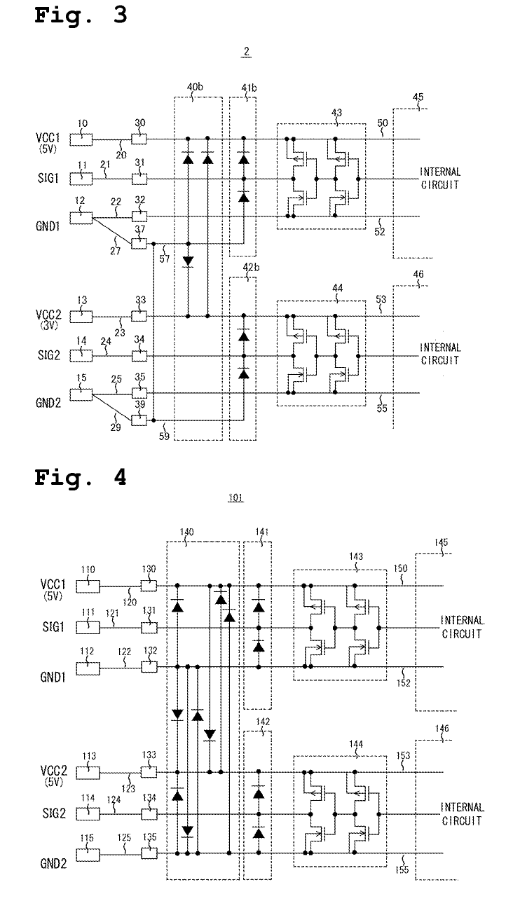

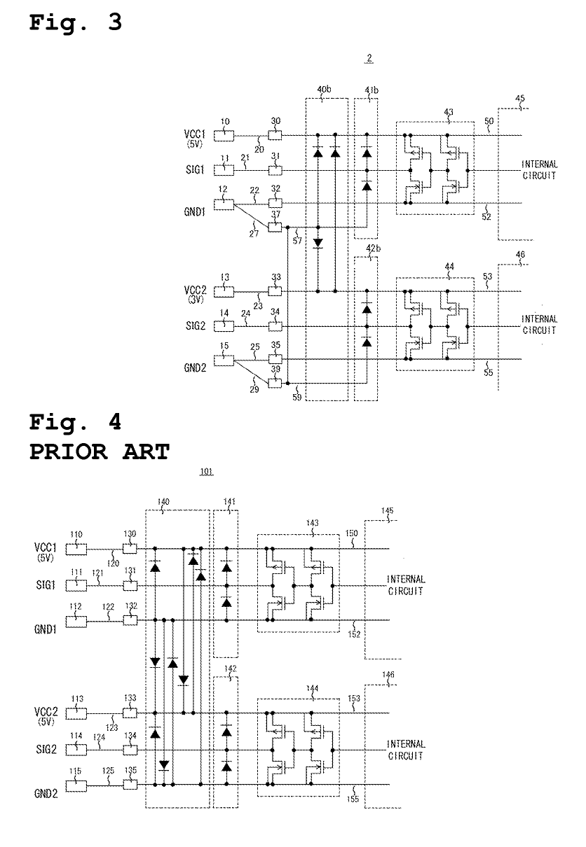

The VCC1 bonding pad 30 and GND1 bonding pad 32 are connected to VCC1 wiring 50 and GND1 wiring 52, respectively, which are provided on the semiconductor substrate. The VCC1 wiring 50 and GND1 wiring 52 are connected to the elements of at least one of the I/O circuit 43 and internal circuit 45 of the first power source system. The I/O circuit 43 inputs or outputs a signal from or to the SIG1 bonding pad 31 and the internal circuit 45 performs signal processing in accordance with a signal inputted from the I/O circuit 43 or outputs a signal to the I/O circuit 43. The specific elements for inputting in the I/O circuit 43, and the subsequently described I/O circuit 44 in FIG. 1 (and FIG. 3 described subsequently) are not illustrated.

A unique characteristic is that a signal ESD protective element section 41a for the prevention of damage caused by ESD to the I/O circuit 43 is connected between the SIG1 bonding pad 31 and the VCC1 ESD protective bonding pad 36 by VCC1 ESD protective wiring 56 and is connected also between the SIG1 bonding pad 31 and the GND1 ESD protective bonding pad 37 by GND1 ESD protective wiring 57. The signal ESD protective element section 41a is defined by a VCC1-side protective element for discharging static electricity applied to the SIG1 terminal 11 with the VCC1 terminal 10 serving as the reference potential terminal from the VCC1 ESD protective wiring 56 to the VCC1 terminal 10 via the VCC1 ESD protective bonding pad 36, and a GND1-side protective element for discharging static electricity applied to the SIG1 terminal 11 with the GND1 terminal 12 serving as the reference potential terminal from the GND1 ESD protective wiring 57 to the GND1 terminal 12 via the GND1 ESD protective bonding pad 37. Diodes or field transistors (MOS transistors with a high threshold value in which the gate is formed by metal wiring), or the like, are preferably used as these protective elements.

Moreover, the VCC2 bonding pad 33 and GND2 bonding pad 35 are connected to the VCC2 wiring 53 and GND2 wiring 55 respectively, which are provided on the semiconductor substrate. The VCC2 wiring 53 and GND2 wiring 55 are connected to the elements of at least one of the I/O circuit 44 and internal circuit 46 of the second power source system. The I/O circuit 44 also inputs or outputs a signal from or to the SIG2 bonding pad 34 as per the I/O circuit 43 and the internal circuit 46 performs signal processing in accordance with a signal inputted from the I/O circuit 44 or outputs a signal to the I/O circuit 44. A signal ESD protective element section 42a for the prevention of damage caused by ESD to the I/O circuit 44 is connected between the SIG2 bonding pad 34 and the VCC2 ESD protective bonding pad 38 by VCC2 ESD protective wiring 58 and is also connected between the SIG2 bonding pad 34 and the GND2 ESD protective bonding pad 39 by GND2 ESD protective wiring 59. The signal ESD protective element section 42a is defined by a VCC2-side protective element for discharging static electricity applied to the SIG2 terminal 14 with the VCC2 terminal 13 serving as the reference potential terminal from the VCC2 ESD protective wiring 58 to the VCC2 terminal 13 via the VCC2 ESD protective bonding pad 38, and a GND2-side protective element for discharging static electricity applied to the SIG2 terminal 14 with the GND2 terminal 15 serving as the reference potential terminal from the GND2 ESD protective wiring 59 to the GND2 terminal 15 via the GND2 ESD protective bonding pad 39.

A power source ESD protective element section 40a of the semiconductor device 1 is defined by a protective element (one diode) that is connected between the VCC1 ESD protective bonding pad 36 and the GND1 ESD protective bonding pad 37 and, more specifically, between the VCC1 ESD protective wiring 56 and GND1 ESD protective wiring 57. The power source ESD protective element section 40a serves to discharge static electricity so that the elements of the I/O circuit 43 or internal circuit 45 are not damaged when static electricity is applied between the VCC1 terminal 10 and GND1 terminal 12. As described above, the VCC1 ESD protective bonding pad 36 and VCC2 ESD protective bonding pad 38 are connected to one another and the GND1 ESD protective bonding pad 37 and GND2 ESD protective bonding pad 39 are connected to one another. More specifically, the VCC1 ESD protective wiring 56 and GND1 ESD protective wiring 57 are connected on the semiconductor substrate to the VCC2 ESD protective wiring 58 and GND2 ESD protective wiring 59, respectively. Therefore, so too in a case where static electricity is applied between the VCC2 terminal 13 and GND2 terminal 15, static electricity is discharged via the power source ESD protective element section 40a, that is, the protective element connected between the VCC1 ESD protective wiring 56 and the GND1 ESD protective wiring 57 via the VCC2 ESD protective wiring 58 and GND2 ESD protective wiring 59. A case where static electricity is applied across another combination of power supply (including ground) terminals is also similar.

An operation in which ESD damage prevention with a power supply terminal or a ground terminal of one power source system as the reference potential terminal is implemented for a signal terminal of the other power source system will be described next. Static electricity applied to the SIG1 terminal 11 with the VCC2 terminal 13 serving as the reference potential terminal is discharged from the VCC1-side protective element defining the signal ESD protective element section 41a to the VCC2 terminal 13 via the VCC1 ESD protective wiring 56, VCC2 ESD protective wiring 58, VCC2 ESD protective bonding pad 38, and bonding wire 28. Static electricity that is applied to the SIG1 terminal 11 with the GND2 terminal 15 serving as the reference potential terminal is similarly discharged from the GND1-side protective element defining the signal ESD protective element section 41a to the GND2 terminal 115 via the GND1 ESD protective wiring 57, GND2 ESD protective wiring 59, GND2 ESD protective bonding pad 39, and a bonding wire 29. Thus, ESD damage prevention with the power supply terminal or the ground terminal of the other power source system serving as the reference potential terminal can be implemented for the SIG1 terminal 11. ESD damage prevention with the power supply terminal or the ground terminal of the other power source system, that is, the VCC1 terminal 10 and GND1 terminal 12 serving as the reference potential terminal can similarly be implemented for the SIG2 terminal 14.

FIG. 2 is a layout diagram representing the whole semiconductor device 1. The inner portions (the inner lead portions) of the terminals (lead terminals) 10 to 15 are connected to the respective bonding pads 30 to 39 by bonding wires 20 to 29. The SIG1 terminals 11 and SIG2 terminals 14, which are the signal terminals, are respectively provided in a plurality; and for each signal terminal a bonding wire 21 or 24, the SIG1 bonding pad 31 or SIG2 bonding pad 34, the signal ESD protective element section 41a or 42a and the I/O circuit 43 or 44 are provided. In FIG. 2, the reference numerals for the SIG1 bonding pad 31 or SIG2 bonding pad 34, signal ESD protective element section 41a or 42a, and so forth are omitted. The GND1 ESD protective wiring 57 or GND2 ESD protective wiring 59 is provided on the outside around each of the bonding pads 30 to 39; the VCC1 ESD protective wiring 56 or VCC2 ESD protective wiring 58 is provided on the inside of each of the bonding pads 30 to 39; the VCC1 wiring 50 or VCC2 wiring 53 is provided on the inside of the VCC1 ESD protective wiring 56 or VCC2 ESD protective wiring 58 and on the outside around the I/O circuit 43 or 44; and the GND1 wiring 52 or GND2 wiring 55 is provided on the inside of the I/O circuit 43 or 44. The protective elements defining the power source ESD protective element section 40a are disposed and divided in the empty spaces of the semiconductor device 1 (that is, in the four corners of the semiconductor device 1 in FIG. 2).

As described above, the semiconductor device 1 makes it possible to reduce the number of protective elements defining the power source ESD protective element section 40a and, as a result, is capable of minimizing and preventing an increase in the chip size. Furthermore, when the damage prevention strength for ESD in the semiconductor device is measured, because the strength barely changes in principle when the VCC1 terminal 10 is taken as the reference potential terminal and when the VCC2 terminal 13 is taken as the reference potential terminal, measurement that is performed by taking the VCC2 terminal 13 as the reference potential terminal can be omitted. Cases where the GND1 terminal 12 is taken as the reference potential terminal and where the GND2 terminal 15 is taken as the reference potential terminal are also the same.

Further, the possibility that power source noise will be transmitted from the VCC1 wiring 50 of the first power source system, that is, the digital power source system to the VCC2 wiring 53 of the second power source system, that is, the analog power source system, via the route along which power source noise that is superimposed on the power source wiring owing to the elements of the digital power source system is transmitted, that is, the route defined by the VCC1 bonding pad 30, bonding wire 20, VCC1 terminal 10, bonding wire 26, VCC1 ESD protective bonding pad 36, VCC1 ESD protective wiring 56, VCC2 ESD protective wiring 58, VCC2 ESD protective bonding pad 38, bonding wire 28, VCC2 terminal 13, bonding wire 23, and the VCC2 bonding pad 33, is also assumed. However, the power source noise is attenuated because the impedance of the plurality of bonding wires in the route is high and, because the power source noise is absorbed by an external power source via the VCC1 terminal 10 and VCC2 terminal 13 that have a comparatively low impedance, the power source noise is extremely small and does not pose a problem. The same is also true of the power source noise superimposed on the ground wiring.

A semiconductor device according to a second preferred embodiment of the present invention will be described next on the basis of FIG. 3. The semiconductor device 2 has, as a plurality of power source systems, a plurality of power source systems of different power supply voltages, that is, a 5V first power source system and a 3V second power source system. The VCC1 terminal 10 of the semiconductor device 2 is connected only to the VCC1 bonding pad 30; the VCC1 ESD protective bonding pad 36 of the above-described semiconductor device 1 does not exist and, therefore, the VCC1 ESD protective wiring 56 also does not exist. Likewise, the VCC2 terminal 13 is connected only to the VCC2 bonding pad 33; the VCC2 ESD protective bonding pad 38 of the semiconductor device 1 does not exist and, therefore, nor does the VCC2 ESD protective wiring 58 exist. However, the GND1 ESD protective bonding pad (first ESD protective bonding pad of the first power source system) 37 and the GND2 ESD protective bonding pad (first ESD protective bonding pad of the second power source system) 39 do exist in the present preferred embodiment. These bonding pads are connected to one another on the semiconductor substrate via the GND1 ESD protective wiring 57 and the GND2 ESD protective wiring 59. Instead of the signal ESD protective element sections 41a and 42a of the semiconductor device 1, the semiconductor device 2 includes signal ESD protective element sections 41b and 42b in which the VCC1-side protective element and VCC2-side protective element are connected to the VCC1 wiring 50 and VCC2 wiring 53, respectively, and the GND1-side protective element and GND2-side protective element are connected to the GND1 ESD protective bonding pad 37 and GND2 ESD protective bonding pad 39, respectively. Instead of the power source ESD protective element section 40a, the semiconductor device 2 includes a power source ESD protective element section 40b that includes a protective element (one diode) between the VCC1 bonding pad 30 and GND1 ESD protective bonding pad 37, a protective element (one diode) between the VCC2 bonding pad 33 and the GND1 ESD protective bonding pad 37, and a protective element (one diode) between the VCC1 bonding pad 30 and VCC2 bonding pad 33.

In the case of the semiconductor device 2, ESD damage prevention in a case where the ground terminal of one power source system serves as the reference potential terminal for the signal terminal of the other power source system, that is, when static electricity is applied to the SIG1 terminal 11 with the GND2 terminal 15 serving as the reference potential terminal and when static electricity is applied to the SIG2 terminal 14 with the GND1 terminal 12 serving as the reference potential terminal, is implemented in the same manner as with semiconductor device 1. ESD damage prevention in a case where the power supply terminal of one power source system serves as the reference potential terminal for the signal terminal of the other power source system, that is, when static electricity is applied to the SIG1 terminal 11 with the VCC2 terminal 13 serving as the reference potential terminal and when static electricity is applied to the SIG2 terminal 14 with the VCC1 terminal 10 serving as the reference potential terminal is implemented in the same manner as for the conventional semiconductor device described above.

The power source ESD protective element 40b of the semiconductor device 2 has a larger number of protective elements in comparison with the power source ESD protective element section 40a of the semiconductor device 1. However, the number of protective elements is reduced in comparison with the number of conventional power source ESD protective elements, whereby an increase in the chip size can be minimized.

Depending on the voltages of the plurality of power source systems, there can also be cases where the VCC1 ESD protective bonding pad 36 and VCC2 ESD protective bonding pad 38 of the semiconductor device 1 exist and the GND1 ESD protective bonding pad 37 and GND2 ESD protective bonding pad 39 do not exist, which is the opposite of the construction of the semiconductor device 2.

Although the terminals and the bonding pads corresponding with the terminals are connected using bonding wires in the preferred embodiments described hereinabove, similar results can also be obtained by using connecting members (bumps, for example) that have a high impedance of a certain level. When the semiconductor substrate is mounted directly on a printed board or the like, the ESD protective bonding pad is connected to the corresponding power supply bonding pad or ground bonding pad by the wiring of the printed board.

The present invention is not limited to or by the above preferred embodiments. A variety of design modifications can be made within the scope of the items appearing in the claims. For example, in the above preferred embodiments, for an understanding of the claims, the description is such that the VCC1 ESD protective bonding pad 36 corresponds with the second ESD protective bonding pad of the first power source system, the GND1 ESD protective bonding pad 37 corresponds with the first ESD protective bonding pad of the first power source system, the VCC2 ESD protective bonding pad 38 corresponds with the second ESD protective bonding pad of the second power source system, and the GND2 ESD protective bonding pad 39 corresponds with the first ESD protective bonding pad of the second power source system, respectively. However, the VCC1 ESD protective bonding pad 36 may correspond with the first ESD protective bonding pad of the first power source system, the GND1 ESD protective bonding pad 37 may correspond with the second ESD protective bonding pad of the first power source system, the VCC2 ESD protective bonding pad 38 may correspond with the first ESD protective bonding pad of the second power source system, and the GND2 ESD protective bonding pad 39 may correspond with the second ESD protective bonding pad of the second power source system. Moreover, although a semiconductor device having two power source systems has been described as the semiconductor device having a plurality of power source systems in the above preferred embodiments, it is understood that the present invention can be applied to all or a portion of the power source systems of a semiconductor device having three or more power source systems.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-8. (canceled)

9. A semiconductor device comprising:
at least a first and a second power source system, the first and second power source systems each including:
a power supply bonding pad, a ground bonding pad, and at least one signal bonding pad arranged on a semiconductor substrate;
an I/O circuit that is connected to each of the power supply bonding pad, the ground bonding pad and the at least one signal bonding pad, and arranged to input or output a signal from or to the signal bonding pad; and
a first ESD protective bonding pad and a signal ESD protective element section connected to the signal bonding pad and the first ESD protective bonding pad; wherein
the first ESD protective bonding pads of the first and second power source systems are connected to one another.

10. The semiconductor device according to claim 9, further comprising a power source ESD protective element section connected to either of the first ESD protective bonding pads of the first and second power source systems.

11. The semiconductor device according to claim 9, wherein each of the first and second power source systems further comprises a power supply terminal connected to the power supply bonding pad, a ground terminal connected to the ground bonding pad, and a signal terminal connected to the signal bonding pad; wherein, in each of the first and second power source systems, the first ESD protective bonding pad is connected to one of the power supply terminal and the ground terminal.

12. The semiconductor device according to claim 11, wherein, in each of the first and second power source systems, the connection between the power supply bonding pad and the power supply terminal, the connection between the ground bonding pad and the ground terminal, the connection between the signal bonding pad and the signal terminal, and the connection between the first ESD protective bonding pad and one of the power supply terminal and the ground terminal, are via bonding wire.

13. The semiconductor device according to claim 9, wherein each of the first and second power source systems further comprises, on the semiconductor substrate, a second ESD protective bonding pad connected to the signal ESD protective element section, and the second ESD protective bonding pads of the first and second power source systems are connected to one another.

14. The semiconductor device according to claim 13, further comprising a power source ESD protective element section connected to either of the first ESD protective bonding pads and to either of the second ESD protective bonding pads of the first and second power source systems.

15. The semiconductor device according to claim 14, wherein each of the first and second power source systems further comprises:
a power supply terminal connected to the power supply bonding pad, a ground terminal connected to the ground bonding pad, and a signal terminal connected to the signal bonding pad; wherein
in each of the first and second power source systems, the first ESD protective bonding pad is connected to one of the power supply terminal and the ground terminal, and the second ESD protective bonding pad is connected to the other of the power supply terminal and the ground terminal.

16. The semiconductor device according to claim 15, wherein, in each of the first and second power source systems, the connection between the power supply bonding pad and the power supply terminal, the connection between the ground bonding pad and the ground terminal, the connection between the signal bonding pad and the signal terminal, the connection between the first ESD protective bonding pad and one of the power supply terminal and the ground terminal, and the connection between the second ESD protective bonding pad and the other of the power supply terminal and the ground terminal, are via bonding wire.

17. The semiconductor device according to claim 13, wherein each of the first and second power source systems further comprises:
a power supply terminal connected to the power supply bonding pad, a ground terminal connected to the ground bonding pad, and a signal terminal connected to the signal bonding pad; wherein
in each of the first and second power source systems, the first ESD protective bonding pad is connected to one of the power supply terminal and the ground terminal, and the second ESD protective bonding pad is connected to the other of the power supply terminal and the ground terminal.

18. The semiconductor device according to claim 17, wherein, in each of the first and second power source systems, the connection between the power supply bonding pad and the power supply terminal, the connection between the ground bonding pad and the ground terminal, the connection between the signal bonding pad and the signal terminal, the connection between the first ESD protective bonding pad and one of the power supply terminal and the ground terminal, and the connection between the second ESD protective bonding pad and the other of the power supply terminal and the ground terminal, are via bonding wire.

19. The semiconductor device according to claim 10, wherein each of the first and second power source systems further comprises a power supply terminal connected to the power supply bonding pad, a ground terminal connected to the ground bonding pad, and a signal terminal connected to the signal bonding pad; wherein, in each of the first and second power source systems, the first ESD protective bonding pad is connected to one of the power supply terminal and the ground terminal.

20. The semiconductor device according to claim 19, wherein, in each of the first and second power source systems, the connection between the power supply bonding pad and the power supply terminal, the connection between the ground bonding pad and the ground terminal, the connection between the signal bonding pad and the signal terminal, and the connection between the first ESD protective bonding pad and one of the power supply terminal and the ground terminal, are via bonding wire.
